(19) United States
(12) Patent Application Publication
(10) Pub. No.: US 2025/0207868 A1
(43) Pub. Date: Jun. 26, 2025

(54) LIQUID COOLER HAVING ALUMINUM BRAZING BEAD STRUCTURE

(71) Applicant: AMULAIRE THERMAL TECHNOLOGY, INC., New Taipei City (TW)

(72) Inventors: CHING-MING YANG, New Taipei City (TW); REUI-JEN YANG, New Taipei City (TW); YI-HSIN HUANG, New Taipei City (TW); KUO-WEI LEE, New Taipei City (TW); TZE-YANG YEH, New Taipei City (TW)

(21) Appl. No.: 18/393,608

(22) Filed: Dec. 21, 2023

(51) Int. Cl. F28F 1/02; F28F 21/08

(52) U.S. Cl. CPC F28F 1/022; F28F 21/084; F28F 21/089; F28F 2275/04

(57) ABSTRACT

A liquid cooler having an aluminum brazing bead structure includes a first outer cover, a second outer cover, a plurality of water holes formed on at least one of the first outer cover and the second outer cover, a liquid flow channel formed between the first outer cover and the second outer cover and in spatial communication with the water holes, at least one divider island integrally formed on the second outer cover and dividing the liquid flow channel into a plurality of sub-flow channels, and one or more open holes formed between the at least one divider island and the first outer cover. An upper surface of the at least one divider island and a lower surface of the first outer cover are brazed together, so that the one or more open holes are formed into one or more blind holes.

### FIELD OF THE DISCLOSURE

The present disclosure relates to liquid coolers, and more particularly to a liquid cooler having an aluminum brazing bead structure.

### BACKGROUND OF THE DISCLOSURE

Currently, water-cooled radiators for automotive IGBT (Insulated Gate Transistor) or ADAS (Advanced Driving Assistance System) are available on the market. Since there are more and more chips and areas that need heat dissipation, a flow channel structure of the automotive water-cooled radiator has many island-shaped structures that separate flow channels in the middle. Accordingly, a cooling liquid can be diverted or recirculated for enabling an overall heat dissipation temperature to be uniform. However, as the automotive water-cooled radiator is developed toward being thinner and larger, a brazing tolerance (gap) between the island-shaped structure and an upper plate cover will become larger. When the brazing tolerance becomes larger, a large-sized brazing void will be generated between the island-shaped structure and the upper plate cover. In addition, when a brazing void rate is greater than 40%, there is a risk of water channel perforation. This situation is even more obvious when a size ratio of the island-shaped structure to the upper plate cover is greater than 5%.

### SUMMARY OF THE DISCLOSURE

In response to the above-referenced technical inadequacies, the present disclosure provides a liquid cooler having an aluminum brazing bead structure.

In order to solve the above-mentioned problems, one of the technical aspects adopted by the present disclosure is to provide a liquid cooler having aluminum brazing bead structure, which includes: a first outer cover, a second outer cover, a plurality of water holes, a liquid flow channel, at least one divider island and one or more open holes. The plurality of water holes are formed on at least one of the first outer cover and the second outer cover, and the liquid flow channel is formed between the first outer cover and the second outer cover and in spatial communication with the plurality of water holes. The at least one divider island is integrally formed on the second outer cover, and divides the liquid flow channel into a plurality of sub-flow channels. The one or more open holes are formed between the at least one divider island and the at least one first outer cover, and an upper surface of the at least one divider island and a lower surface of the at least first outer cover are brazed together, so that the one or more open holes are formed as one or more blind holes, and a ratio of a projected area of the upper surface of the at least one divider island to a projected area of the lower surface of the first outer cover is greater than 5%.

In one of the possible or preferred embodiments, the first outer cover and the second outer cover are made of aluminum or aluminum alloy.

In one of the possible or preferred embodiments, the one or more open holes have a circular, quasi-circular, rectangular or irregular shape.

In one of the possible or preferred embodiments, the one or more open holes are arranged at intervals, and a ratio of an interval length between adjacent ones of the open holes to a maximum length of the at least one divider island ranges between 10% and 20%.

In one of the possible or preferred embodiments, the one or more open holes are formed on a top portion of the at least one divider island, and a ratio of a total projected area of the open holes formed on the at least one divider island to a projected area of the upper surface of the at least one divider island ranges between 3% and 10%.

In one of the possible or preferred embodiments, the at least one divider island is more than one, and the divider islands are integrally formed on the second outer cover.

In one of the possible or preferred embodiments, at least one fin structure is provided in the liquid flow channel, and the at least one fin structure is a wavy fin structure, a pin column fin structure or a lanced fin structure.

In one of the possible or preferred embodiments, the first outer cover and the second outer cover are each a composite material pre-pressed with brazing preforms.

In one of the possible or preferred embodiments, a metal layer is formed on an upper surface of the first outer cover.

In one of the possible or preferred embodiments, the metal layer is a cold sprayed copper layer.

In one of the possible or preferred embodiments, the at least one divider island has a rectangular, square, or irregular shape.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic top view of a first embodiment of the present disclosure;

FIG. 2 is a schematic cross-sectional view taken along line II-II of FIG. 1;

FIG. 3 is a schematic diagram of a modified embodiment of an open hole according to the present disclosure;

FIG. 4 is a schematic diagram of a modified embodiment of the open hole according to the present disclosure;

FIG. 5 is a schematic diagram of a modified embodiment of the open hole according to the present disclosure;

FIG. 6 is a schematic diagram of a modified embodiment of a divider island according to the present disclosure;

FIG. 7 is a schematic cross-sectional view of a second embodiment of the present disclosure;

FIG. 8 a schematic cross-sectional view of a third embodiment of the present disclosure;

FIG. 9 is a schematic cross-sectional view of a fourth embodiment of the present disclosure;

FIG. 10 is a schematic cross-sectional view of a fifth embodiment of the present disclosure;

FIG. 11 is a schematic top view of a sixth embodiment of the present disclosure;

FIG. 12 is a schematic top view of a seventh embodiment of the present disclosure; and

FIG. 13 is a schematic top view of an eighth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

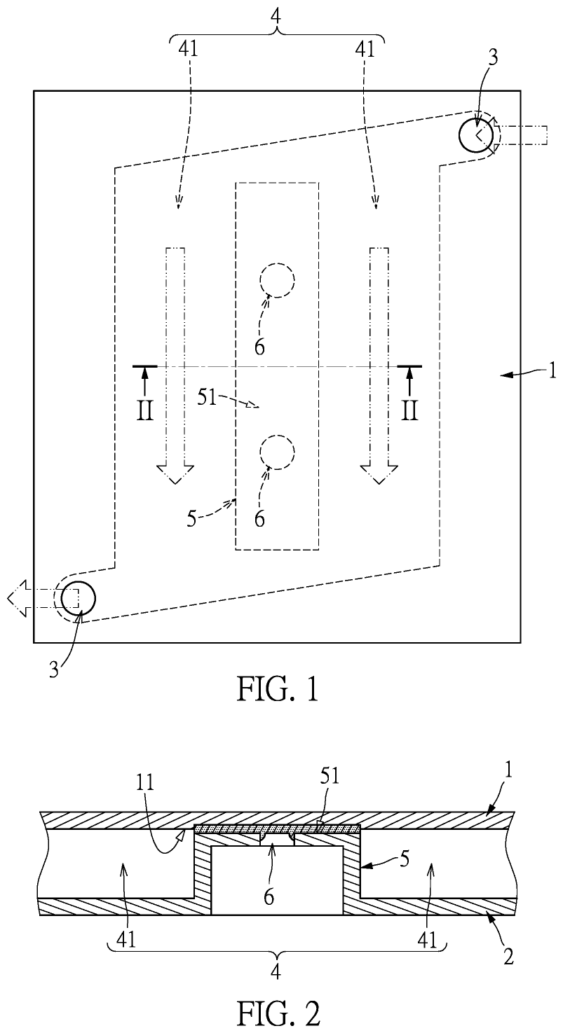

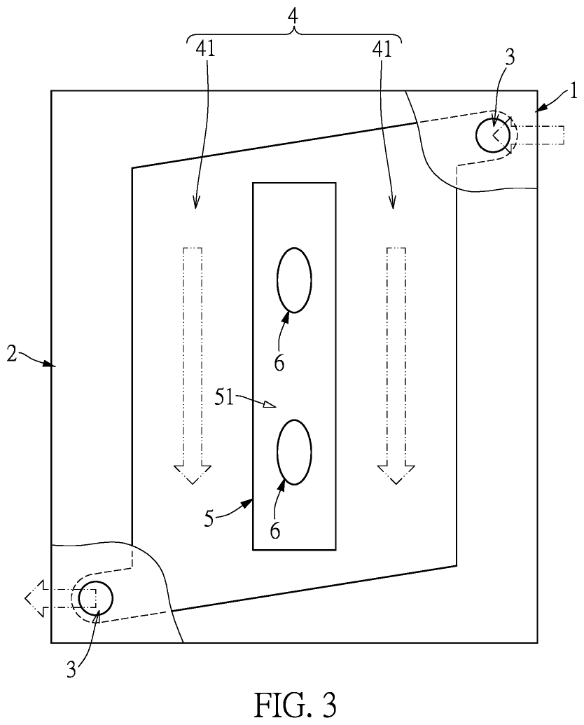

Reference is made to FIG. 1 and FIG. 2, which show the first embodiment of the present disclosure. The present embodiment provides a liquid cooler having an aluminum brazing bead structure, which includes: a first outer cover 1, a second outer cover 2, a plurality of water holes 3, a liquid flow channel 4, at least one divider island 5, and one or more open holes 6.

The first outer cover 1 and the second outer cover 2 may be made of aluminum or aluminum alloy. In this embodiment, the first outer cover 1 may be an upper plate cover, and the second outer cover 2 may be a lower plate cover. The water holes 3 are formed on at least one of the first outer cover 1 and the second outer cover 2. In this embodiment, a quantity of the water holes 3 is two, and the two water holes 3 are both formed on the first outer cover 1. Alternatively, one of the water holes 3 is formed on the first outer cover 1, and another one of the water holes 3 is formed on the second outer cover 2, or the two water holes 3 are both formed on the second outer cover 2. However, the present disclosure is not limited thereto. Moreover, one of the water holes 3 may be a water inlet hole, and another one of the water holes 3 may be a water outlet hole.

The liquid flow channel 4 is formed between the first outer cover 1 and the second outer cover 2, and is in spatial communication with the two water holes 3, so that a cooling liquid (water or ethylene glycol) can enter the liquid flow channel 4 through one of the water holes 3 and flow out of the liquid flow channel 4 through another one of the water holes 3.

The divider island 5 can be referred to as a medial island or an island-shaped divider. The divider island 5 is integrally formed on the second outer cover 2, and the divider island 5 divides the liquid flow channel 4 into left and right sub-flow channels 41. Furthermore, a ratio of a projected area of an upper surface 51 of the divider island 5 to a projected area of a lower surface 11 of the first outer cover 1 is greater than 5%.

In the present embodiment, the divider island 5 is integrally formed on the second outer cover 2 by stamping, so that an interior of the divider island 5 is hollow, and a flow channel structure formed between the first outer cover 1 and the second outer cover 2 can be thinned. In this way, the material and manufacturing costs can be saved. Although the liquid cooler can be made thinner, lighter, and less expensive, a tolerance (gap) between the upper surface 51 of the divider island 5 and the lower surface 11 of the first outer cover 1 will become larger, so that a brazing void rate between the upper surface 51 of the divider island 5 and the lower surface 11 of the first outer cover 1 is more likely to be greater than 40%, thus causing water channel perforation. This situation is particularly obvious when the ratio of the projected area of the upper surface 51 of the divider island 5 to the projected area of the lower surface 11 of the first outer cover 1 is greater than 5%.

Therefore, the one or more open holes 6 are formed between the divider island 5 and the first outer cover 1, and the upper surface 51 of the divider island 5 and the lower surface 11 of the first outer cover 1 are brazed together, so that the one or more open holes 6 are formed as one or more blind holes. That is to say, after brazing, the open hole 6 (which is originally a through hole that opens at both sides) is formed into the blind hole (i.e., an open hole that is closed at a single side), so as to avoid weakening of the structural strength caused by the through hole. In the present embodiment, a quantity of the open holes 6 is two, and the two open holes 6 are formed at intervals on a top portion of the divider island 5. However, each of the two open holes 6 can also be formed at a position of the first outer cover 1 that corresponds to the top portion of the divider island 5. The one or more open holes 6 are formed between the divider island 5 and the first outer cover 1, so that a large amount of gas generated during brazing can be smoothly discharged through the one or more open holes 6 to reduce the brazing void rate. In this way, the water channel perforation can be avoided.

In addition, after the first outer cover 1 and the divider island 5 are brazed, there will be no exchange of gas or liquid between the open hole 6 and the liquid flow channel 4 (that is, gas flows to the liquid flow channel 4 from the open hole 6, or vice versa, or liquid flows to the open hole 6 from the liquid flow channel 4, or vice versa). Moreover, there will be no threaded nails or rivet structures on the divider island 5.

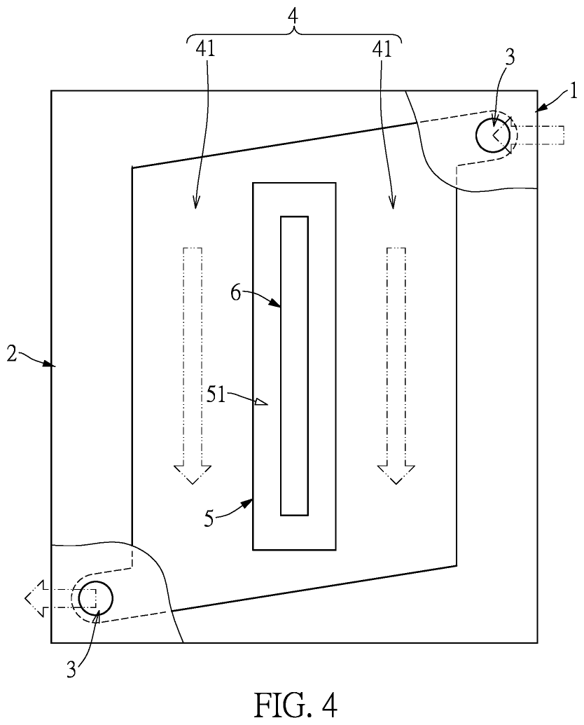

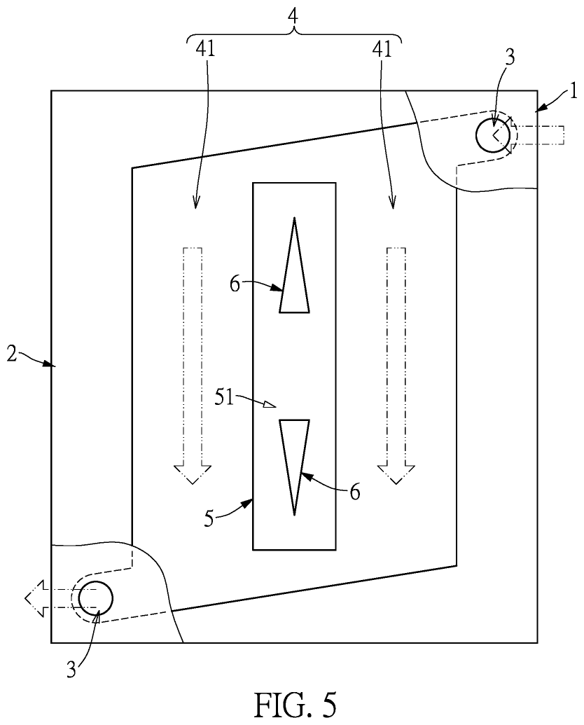

In the present embodiment, the open hole 6 has a circular shape. In other embodiments, the open hole 6 can also have a quasi-circular (oval) shape (as shown in FIG. 3), a rectangular shape (as shown in FIG. 4), or other irregular shapes (as shown in FIG. 5), but the present disclosure is not limited thereto.

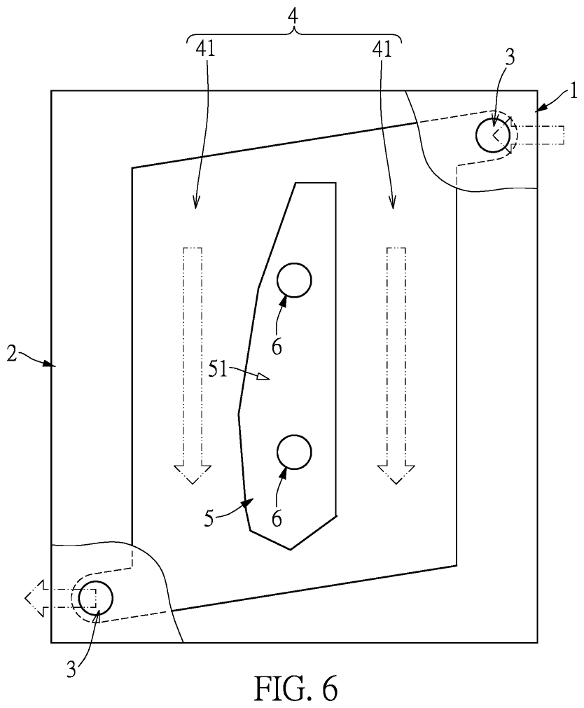

In the present embodiment, the divider island 5 is rectangular in shape. In other embodiments, the divider island 5 can also have a square shape or other irregular shapes (as shown in FIG. 6), but the present disclosure is not limited thereto.

### Second Embodiment

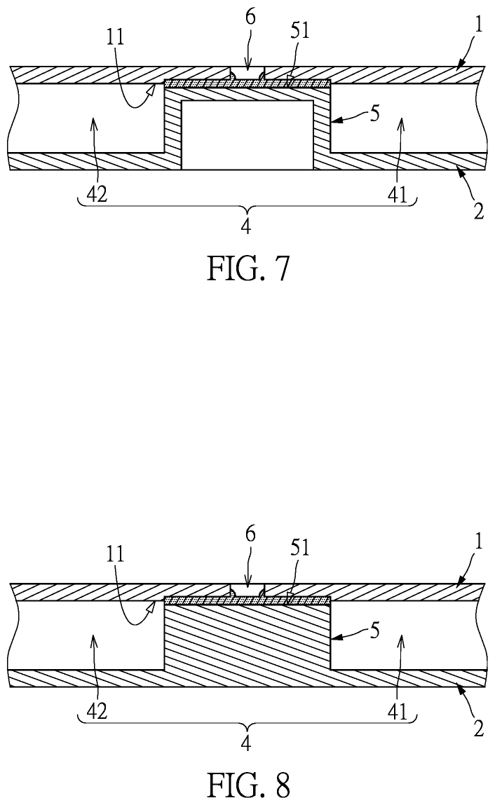

Reference is made to FIG. 7, which shows the second embodiment of the present disclosure. The present embodiment is substantially the same as the first embodiment, and the differences are explained as follows.

In the present embodiment, the open hole 6 is formed at a position of the first outer cover 1 that corresponds to the top portion of the divider island 5.

### Third Embodiment

Reference is made to FIG. 8, which shows the third embodiment of the present disclosure. The present embodiment is substantially the same as the first embodiment, and the differences are explained as follows.

In the present embodiment, the divider island 5 is integrally formed on the second outer cover 2, and the interior of the divider island 5 is solid. That is, the divider island 5 can be integrally formed on the second outer cover 2 by metal casting, or can be integrally formed on the second outer cover 2 by metal injection molding (MIM), so that the interior of the divider island 5 is solid.

### Fourth Embodiment

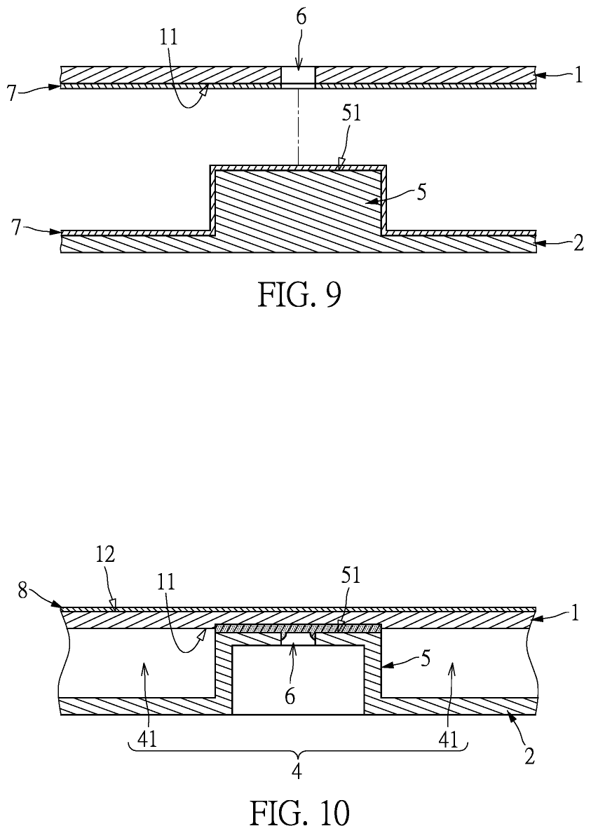

Reference is made to FIG. 9, which shows the fourth embodiment of the present disclosure. The present embodiment is substantially the same as the first embodiment, and the differences are explained as follows.

In the present embodiment, the first outer cover 1 and the second outer cover 2 are respectively made of a composite material that is pre-pressed with brazing preforms 7 (brazing preform). Furthermore, the lower surface 11 of the first outer cover 1 is pre-pressed with the brazing preforms 7, and the upper surface 51 of the divider island 5 is also pre-pressed with the brazing preforms 7.

### Fifth Embodiment

Reference is made to FIG. 10, which shows the fifth embodiment of the present disclosure. The present embodiment is substantially the same as the first embodiment, and the differences are explained as follows.

In the present embodiment, a metal layer 8 is further formed on an upper surface 12 of the first outer cover 1. Furthermore, the metal layer 8 formed on the upper surface 12 of the first outer cover 1 is a cold sprayed copper layer.

### Sixth Embodiment

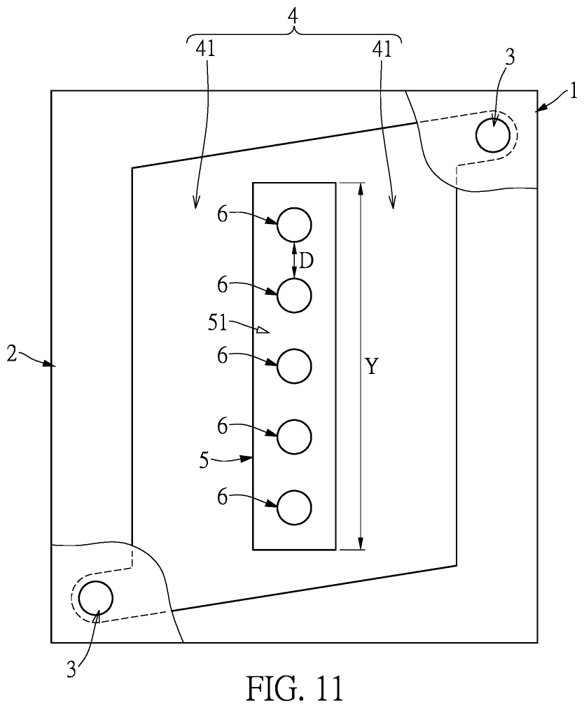

Reference is made to FIG. 11, which shows the sixth embodiment of the present disclosure. The present embodiment is substantially the same as the first embodiment, and the differences are explained as follows.

In the present embodiment, the open holes 6 are arranged at intervals. The open holes 6 are formed at intervals on the top portion of the divider island 5, and a ratio of an interval length D between adjacent ones of the open holes 6 to a maximum length Y of the divider island 5 ranges between 10% and 20%, so that a large amount of gas generated during brazing can be discharged more evenly through the open holes 6 to reduce the brazing void rate. In this way, the occurrence of water channel perforations can be avoided.

In other embodiments, the open holes 6 may also be formed at intervals at positions of the first outer cover 1 that correspond to the top portion of the divider island 5.

### Seventh Embodiment

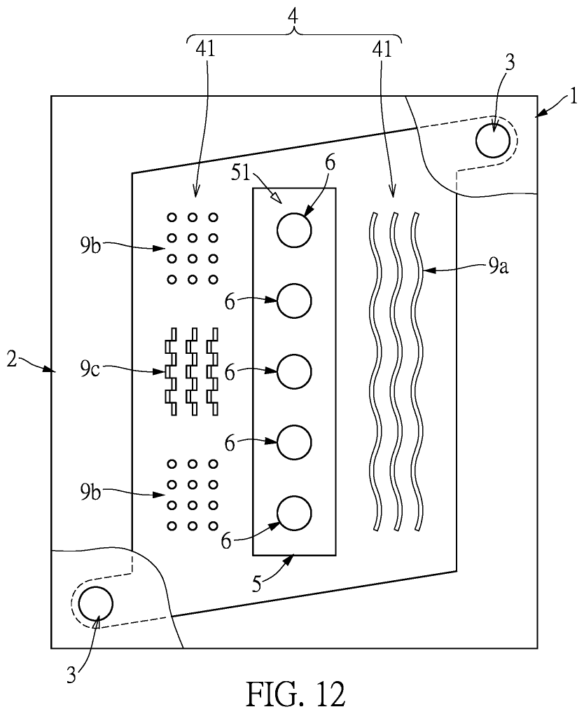

Reference is made to FIG. 12, which shows the seventh embodiment of the present disclosure. The present embodiment is substantially the same as the first embodiment, and the differences are explained as follows.

In the present embodiment, at least one fin structure is provided in the liquid flow channel 4, and the at least one fin structure can be a wavy fin structure 9a, a pin fin structure 9b, or a lanced fin structure 9c.

In addition, the wavy fin structure 9a, the pin fin structure 9b, or the lanced fin structure 9c can be integrally formed on at least one of the first outer cover 1 and the second outer cover 2.

### Eighth Embodiment

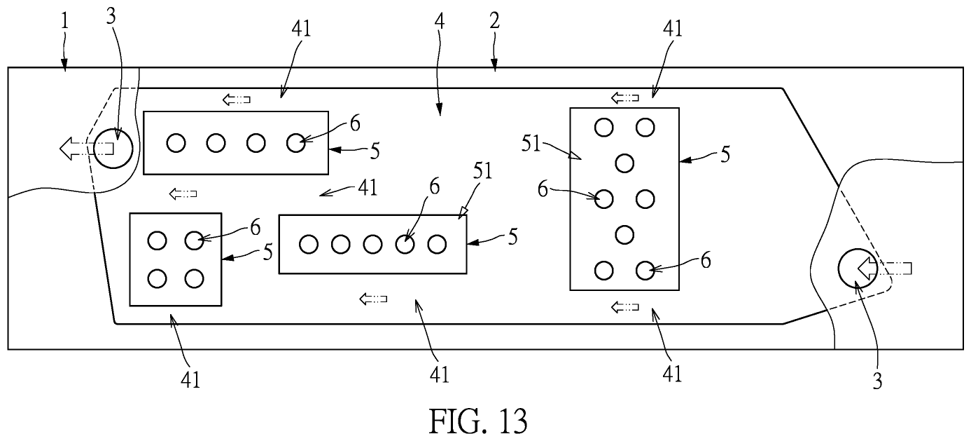

Reference is made to FIG. 13, which shows the eighth embodiment of the present disclosure. The present embodiment is substantially the same as the first embodiment, and the differences are explained as follows.

In the present embodiment, the at least one divider island 5 is more than one. The divider islands 5 are integrally formed on the second outer cover 2, and the divider islands 5 divide the liquid flow channel 4 into a plurality of sub-flow channels 41. The open holes 6 are formed on the top of one single divider island 5, and a ratio of a total projected area of the open holes 6 formed on the single divider island 5 to a projected area of the upper surface 51 of the single divider island 5 ranges between 3% to 10%, so that a large amount of gas generated during brazing can be more effectively discharged through these open holes 6 to reduce the brazing void rate. In this way, the occurrence of water channel perforations can be avoided. Moreover, the shape of the single divider island 5 can be rectangular, square, or irregular.

In conclusion, in the liquid cooler having the aluminum brazing bead structure provided by the present disclosure, by virtue of “a first outer cover, a second outer cover, a plurality of water holes, a liquid flow channel, at least one divider island, and one or more open holes,” “the plurality of water holes being formed on at least one of the first outer cover and the second outer cover, and the liquid flow channel being formed between the first outer cover and the second outer cover and in spatial communication with the plurality of water holes,” “the at least one divider island being integrally formed on the second outer cover, and dividing the liquid flow channel into a plurality of sub-flow channels,” and “the one or more open holes being formed between the at least one divider island and the first outer cover, and an upper surface of the at least one divider island and a lower surface of the first outer cover being brazed together, so that the one or more open holes are formed into one or more blind holes, and a ratio of a projected area of the upper surface of the at least one divider island to a projected area of the lower surface of the first outer cover is greater than 5%,” a large amount of gas generated during brazing can be smoothly discharged through the one or more open holes, thereby reducing the brazing void rate and avoiding the occurrence of water channel perforations.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A liquid cooler having an aluminum brazing bead structure, comprising: a first outer cover, a second outer cover, a plurality of water holes, a liquid flow channel, at least one divider island, and one or more open holes, wherein the plurality of water holes are formed on at least one of the first outer cover and the second outer cover, and the liquid flow channel is formed between the first outer cover and the second outer cover and in spatial communication with the plurality of water holes; wherein the at least one divider island is integrally formed on the second outer cover, and divides the liquid flow channel into a plurality of sub-flow channels; wherein the one or more open holes are formed between the at least one divider island and the first outer cover, and an upper surface of the at least one divider island and a lower surface of the first outer cover are brazed together, so that the one or more open holes are formed into one or more blind holes, and a ratio of a projected area of the upper surface of the at least one divider island to a projected area of the lower surface of the first outer cover is greater than 5%.

2. The liquid cooler according to claim 1, wherein the first outer cover and the second outer cover are made of aluminum or aluminum alloy.

3. The liquid cooler according to claim 1, wherein the one or more open holes have a circular, quasi-circular, rectangular, or irregular shape.

4. The liquid cooler according to claim 1, wherein the open holes are arranged at intervals, and a ratio of an interval length between adjacent ones of the open holes to a maximum length of the at least one divider island ranges between 10% and 20%.

5. The liquid cooler according to claim 1, wherein the open holes are formed on a top portion of the at least one divider island, and a ratio of a total projected area of the open holes formed on the at least one divider island to a projected area of the upper surface of the at least one divider island ranges between 3% and 10%.

6. The liquid cooler according to claim 1, wherein the at least one divider island is more than one, and the divider islands are integrally formed on the second outer cover.

7. The liquid cooler according to claim 1, wherein at least one fin structure is provided in the liquid flow channel, and the at least one fin structure is a wavy fin structure, a pin column fin structure, or a lanced fin structure.

8. The liquid cooler according to claim 1, wherein the first outer cover and the second outer cover are each a composite material pre-pressed with brazing preforms.

9. The liquid cooler according to claim 1, wherein a metal layer is formed on an upper surface of the first outer cover.

10. The liquid cooler according to claim 9, wherein the metal layer is a cold sprayed copper layer.

11. The liquid cooler according to claim 1, wherein the at least one divider island has a rectangular, square, or irregular shape.
